(19) United States
(12) Patent Application Publication
(10) Pub. No.: US 2018/0040382 A1
(43) Pub. Date: Feb. 8, 2018

(54) SHIFT REGISTERS AND DRIVING METHODS THEREOF, GATE DRIVING APPARATUS AND DISPLAY APPARATUSES

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Honggang Gu, Beijing (CN); Xianjie Shao, Beijing (CN); Jie Song, Beijing (CN); Qianqian Wang, Beijing (CN)

(21) Appl. No.: 15/647,583

(22) Filed: Jul. 12, 2017

(30) Foreign Application Priority Data
Aug. 4, 2016 (CN) 201610632651.1

(51) Int. Cl. G11C 19/28; G09G 3/36

(52) U.S. Cl. CPC G11C 19/287; G09G 3/3674; G09G 2310/0286; G09G 2300/0408

(57) ABSTRACT

Embodiments of the present disclosure disclose a shift register. The shift register comprises an input circuit configured to control a voltage of a first node, an output circuit configured to control an output signal of a signal output terminal, a first reset circuit configured to reset the voltage of the first node, a second reset circuit configured to reset the output signal, a pull-up control circuit configured to control the voltage of the first node according to the voltage of the second node, and a pull-down control circuit configured to control the voltage of the second node according to the voltage of the first node and control the voltage of the second node to be an effective voltage in response to the voltage of the first node being a non-effective voltage. Further, a gate driving apparatus, an array substrate, and a display apparatus are also proposed.

### CROSS-REFERENCE TO RELATED APPLICATION(S)

This application claims priority to the Chinese Patent Application No. 201610632651.1, filed on Aug. 4, 2016, entitled “SHIFT REGISTERS AND DRIVING METHODS THEREOF, GATE DRIVING APPARATUS AND DISPLAY APPARATUSES”, which is incorporated herein by reference in its entirety.

### TECHNICAL FIELD

The present disclosure relates to the field of display technology, and more particularly, to shift registers and driving methods thereof, gate driving apparatuses, array substrates, and display apparatuses.

### BACKGROUND

Liquid Crystal Displays (LCDs for short) have advantages such as low radiation, small size and low energy consumption, etc., and are widely used in electronic products such as a notebook computer, a flat panel television or a mobile phone etc. A liquid crystal display is comprised of pixel units arranged in a matrix form. During display of the liquid crystal display, a data driving circuit may latch input display data and clock signals according to timing, convert them into analog signals and then input the analog signals into a data line of a liquid crystal panel. A gate driving circuit may convert the input clock signal into a voltage which controls turn-on/turn-off of the pixel units through a shift register and applies it to gate lines of the liquid crystal display line by line.

In order to reduce the production cost of the liquid crystal display, the existing gate driving circuit usually uses the Gate Driver on Array (GOA for short) technology to integrate a gate switch circuit of a Thin Film Transistor (TFT) onto an array substrate of the display panel to form scan driving for the display panel. This gate driving circuit which achieves integration on the array substrate using the GOA technology is also referred to as a GOA circuit or a shift register circuit. A display apparatus using the GOA circuit reduces the cost in terms of the material and the manufacturing process due to the step of binding a driving circuit is omitted.

However, the GOA technology has inherent problems in terms of service life and output stability etc. In GOA design for design of a product, how to use fewer circuit elements to achieve functions of the shift register and reduce a noise at an output terminal to maintain a long-term and stable operation of the gate driving circuit is key issues of the GOA design.

### SUMMARY

The embodiments of the present disclosure provide a shift register and a driving method thereof, a gate driving apparatus, a substrate, and a display apparatus, which can reduce the noise at the output terminal of the shift register and improve the stability of the operations.

According to an aspect of the present disclosure, there is provided a shift register, comprising an input circuit, an output circuit, a first reset circuit, a second reset circuit, a pull-up control circuit, and a pull-down control circuit. The input circuit is coupled to a signal input terminal, a first voltage signal terminal and a first node and configured to supply a first voltage signal from the first voltage signal terminal to the first node according to an input signal from the signal input terminal. The output circuit is coupled to a first clock signal terminal, a signal output terminal and the first node and configured to supply a first clock signal from the first clock signal terminal to the signal output terminal as an output signal according to the voltage of the first node. The first reset circuit is coupled to a reset signal terminal, a second voltage signal terminal and the first node and configured to supply a second voltage signal from the second voltage signal terminal to the first node according to a reset signal from the reset signal terminal, to reset the voltage of the first node. The second reset circuit is coupled to a second clock signal terminal, a third voltage signal terminal, a second node and the signal output terminal and configured to supply a third voltage signal from the third voltage signal terminal to the signal output terminal according to a second clock signal from the second clock signal terminal or a voltage of the second node, to reset the output signal. The pull-up control circuit is coupled to the third voltage signal terminal, the first node and the second node and configured to control the voltage of the first node according to the voltage of the second node. The pull-down control circuit is coupled to the second clock signal terminal, the first node, the second node and the third voltage signal terminal and configured to control the voltage of the second node according to the voltage of the first node and configured to control the voltage of the second node to be an effective voltage in response to the voltage of the first node being a non-effective voltage.

In an embodiment of the present disclosure, the input circuit may comprise a first transistor having a control electrode coupled to the signal input terminal, a first electrode coupled to the first voltage signal terminal and a second electrode coupled to the first node.

In an embodiment of the present disclosure, the output circuit may comprise a third transistor and a first capacitor. The third transistor has a control electrode coupled to the first node, a first electrode coupled to the first clock signal terminal and a second electrode coupled to the signal output terminal. The first capacitor is coupled between the first node and the signal output terminal.

In an embodiment of the present disclosure, the first reset circuit may comprise a second transistor having a control electrode coupled to the reset signal terminal, a first electrode coupled to the second voltage signal terminal and a second electrode coupled to the first node.

In an embodiment of the present disclosure, the second reset circuit may comprise a fourth transistor and a fifth transistor. The fourth transistor has a control electrode coupled to the second clock signal terminal, a first electrode coupled to the third voltage signal terminal, and a second electrode coupled to the signal output terminal. The fifth transistor has a control electrode coupled to the second node, a first electrode coupled to the third voltage signal terminal and a second electrode coupled to the signal output terminal.

In an embodiment of the present disclosure, the pull-up control circuit may comprise a seventh transistor having a control electrode coupled to the second node, a first electrode coupled to the third voltage signal terminal and a second electrode coupled to the first node.

In an embodiment of the present disclosure, the pull-down control circuit may comprise a sixth transistor, an eighth transistor and a second capacitor. The sixth transistor has a control electrode coupled to the first node, a first electrode coupled to the third voltage signal terminal and a second electrode coupled to the second node. The eighth transistor has a control electrode and a first electrode both coupled to the second clock signal terminal and a second electrode coupled to the second node. The second capacitor is coupled between the second node and the third voltage signal terminal.

In an embodiment of the present disclosure, transistors used in various circuits may be N-type transistors or P-type transistors.

In an embodiment of the present disclosure, the first clock signal has an opposite phase to that of the second clock signal.

According to another aspect of the present disclosure, there is provided a method for driving the shift register described above. In this method, the first voltage signal terminal outputs the first voltage signal at a high level, the second voltage signal terminal outputs the second voltage signal at a low level, and the third voltage signal terminal outputs the third voltage signal at a low level. The input signal at a high level is supplied to the signal input terminal and the first clock signal at a low level is supplied to the first clock signal terminal during a first period of time, so that the voltage of the first node reaches a high level, the voltage of the second node is at a low level, and the signal output terminal outputs the output signal at a low level. The first clock signal at a high level is supplied to the first clock signal terminal during a second period of time, so that the voltage of the first node further increases, the voltage of the second node is maintained at a low level, and the signal output terminal outputs the output signal at a high level. The reset signal at a high level is supplied to the reset signal terminal and the second clock signal at a high level is supplied to the second clock signal terminal during a third period of time, so that the voltage of the first node is reset to a low level, the voltage of the second node changes to a high level, and the signal output terminal outputs the output signal at a low level. The voltage of the second node is controlled to be maintained at a high level during a fourth period of time, so that the voltage of the first node is maintained at a low level and the output signal is maintained at a low level. The second clock signal at a high level is supplied to the second clock signal terminal during a fifth period of time, so that the voltage of the second node is maintained at a high level, the voltage of the first node is maintained at a low level, and the output signal is maintained at a low level.

In an embodiment of the present disclosure, the first voltage signal terminal outputs the second voltage signal at a low level, and the second voltage signal terminal outputs the first voltage signal at a high level. Further, the reset signal is supplied to the signal input terminal, and the input signal is supplied to the reset signal terminal.

According to another aspect of the present disclosure, there is provided a gate driving apparatus, comprising: multiple cascaded shift registers, wherein each stage of shift registers is the shift registers described above. In the gate driving apparatus, the signal output terminal of each stage of shift registers is coupled to the signal input terminal of the next stage of shift registers, and the rest signal terminal of each stage of shift registers is coupled to the signal output terminal of the next stage of shift registers.

In an embodiment of the present disclosure, clock signals for the first clock signal terminals of two adjacent stages of shift registers have opposite phases to each other, and clock signals for the second clock signal terminals of the two adjacent stages of shift registers have opposite phases to those of corresponding first clock signal terminals, respectively.

According to another aspect of the present disclosure, there is provided an array substrate comprising the gate driving apparatus described above.

According to another aspect of the present disclosure, there is provided a display apparatus comprising the array substrate described above.

### BRIEF DESCRIPTION OF THE DRAWINGS

In order to more clearly illustrate the technical solutions of the present disclosure, the accompanying drawings of the embodiments will be briefly described below. It is to be understood that the accompanying drawings described below are merely some embodiments of the present disclosure and are not intended to be limiting of the present disclosure, wherein in the accompanying drawings:

FIG. 1 is a schematic block diagram of a shift register according to an embodiment of the present disclosure;

FIG. 2 is a schematic circuit diagram of a shift register according to an embodiment of the present disclosure;

FIG. 3 is a diagram of the shift register shown in FIG. 2 during a reverse scan;

FIG. 4 is a timing diagram of various signals of the shift register shown in FIG. 2;

FIG. 5 is a schematic flowchart of a method for driving a shift register according to an embodiment of the present disclosure; and

FIG. 6 is a schematic structural diagram of a gate driving apparatus according to an embodiment of the present disclosure.

### DETAILED DESCRIPTION

In order to make the purposes, technical solutions and advantages of the embodiments of the present disclosure more clear, the technical solutions according to the embodiments of the present disclosure will be described clearly and completely in conjunction with the accompanying drawings. Obviously, the described embodiments are merely a part of the embodiments of the present disclosure, instead of all the embodiments. All other embodiments obtained by one of ordinary skill in the art based on the described embodiments without contributing any creative labor are also within the scope of the present disclosure.

In the following, unless otherwise specified, an expression “an element A is coupled to an element B” means that the element A is connected to the element B “directly” or “indirectly” via one or more other elements.

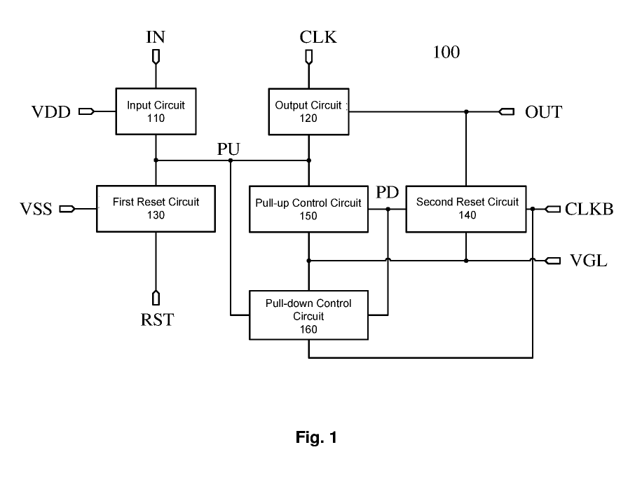

FIG. 1 illustrates a schematic block diagram of a shift register 100 according to an embodiment of the present disclosure. As shown in FIG. 1, the shift register 100 may comprise an input circuit 110, an output circuit 120, a first reset circuit 130, a second reset circuit 140, a pull-up control circuit 150, and a pull-down control circuit 160.

The input circuit 110 may be coupled to the first voltage signal terminal VDD, the signal input terminal IN and the first node PU. The input circuit 110 may supply a first voltage signal Vdd from the first voltage signal terminal VDD to the first node PU (also referred to as “a pull-up node”) under the control of an input signal INPUT from the signal input terminal IN.

The output circuit 120 may be coupled to the first node PU, a first clock signal terminal CLK and a signal output terminal OUT. The output circuit 120 may control an output signal OUTPUT of the signal output terminal OUT under the control of a voltage of the first node PU. Specifically, when the voltage of the first node PU is an effective voltage, the output circuit 120 may supply a first clock signal CLK1 to the signal output terminal OUT.

The first reset circuit 130 may be coupled to the first node PU, a second voltage signal terminal VSS and a reset signal terminal RST. The first reset circuit 130 may supply a second voltage signal Vss from the second voltage signal terminal VSS to the first node PU under the control of a reset signal RESET from the reset signal terminal RST, to reset the voltage of the first node PU.

The second reset circuit 140 may be coupled to a second clock signal terminal CLKB, a third voltage signal terminal VGL, a second node PD (also referred to as “a pull-down node”) and the signal output terminal OUT. The second reset circuit 140 may supply a third voltage signal Vgl from the third voltage signal terminal VGL to the signal output terminal OUT under the control of a voltage of the second node PD or a second clock signal CLK2 from the second clock signal terminal CLKB, to reset the output signal OUTPUT.

The pull-up control circuit 150 may be coupled to the first node PU, the second node PD and the third voltage signal terminal VGL. The pull-up control circuit 150 may supply the third voltage signal Vgl to the first node PU under the control of the voltage of the second node PD. Specifically, when the voltage of the second node PD is an effective voltage, the pull-up control circuit 150 supplies the third voltage signal Vgl to the first node PU, so that the voltage of the first node PU is the same as the voltage of the third voltage signal Vgl.

The pull-down control circuit 160 may be coupled to the first node PU, the second node PD, the second clock signal terminal CLKB and the third voltage signal terminal VGL. The pull-down control circuit 160 may control the voltage of the second node PD under the control of the voltage of the first node PU. Specifically, when the voltage of the first node PU is an effective voltage, the third voltage signal Vgl is supplied to the second node PD, so that the voltage of the second node PD is the same as the voltage of the third voltage signal Vgl. In addition, the pull-down control circuit 160 may further control the voltage of the second node PD to be an effective voltage when the voltage of the first node PU is a non-effective voltage.

In the embodiment of the present disclosure, the non-effective voltage refers to a voltage at which the output circuit 120 is disabled. In a case of the non-effective voltage, the output circuit 120 does not operate and cannot supply the first clock signal to the signal output terminal OUT. Correspondingly, the effective voltage refers to a voltage at which the output circuit 120 is enabled. In a case of the effective voltage, the output circuit 120 operates to supply the first clock signal to the signal output terminal OUT.

In the embodiment of the present disclosure, the first voltage signal Vdd is an operating voltage of the shift register 100, which is a high level signal, the second voltage signal Vss is a low level signal, the third voltage signal Vgl is also a low level signal, but the second voltage signal terminal VSS and the third voltage signal terminal VGL are not connected.

In the embodiment of the present disclosure, the first clock signal CLK1 and the second clock signal CLK2 have the same signal period but opposite phases.

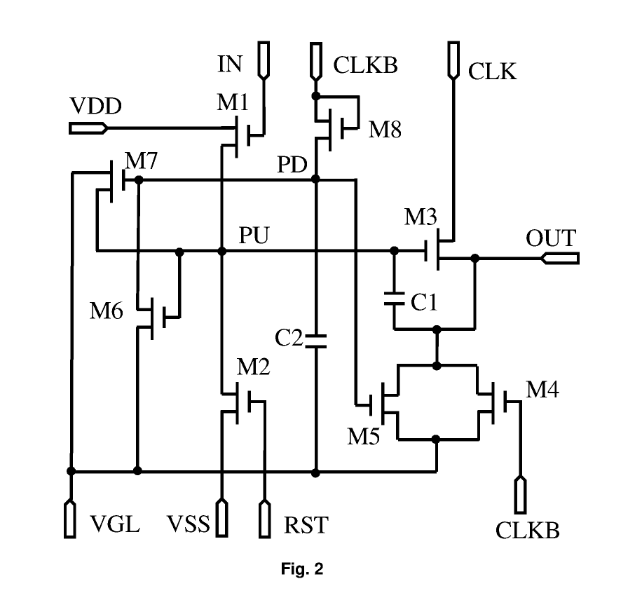

FIG. 2 illustrates an exemplary circuit diagram of the shift register 100 shown in FIG. 1. In the embodiment, the transistor used may be an N-type transistor or a P-type transistor. In particular, the transistor may be an N-type or P-type Metal-Oxide-Semiconductor Field Effect Transistor (MOSFET), or an N-type or P-type Bipolar Junction Transistor (BJT). In the embodiment of the present disclosure, a gate of the transistor is referred to as a control electrode. As a source and a drain of the transistor are symmetrical, the source and the drain are not distinguished, i.e., the source of the transistor is a first electrode (or a second electrode) and the drain of the transistor is a second electrode (or a first electrode). Further, any controlled switch device having a gated signal input may be used to implement functions of the transistor A controlled intermediate terminal of the switch device for receiving a control signal (e.g., for turning on and off the controlled switch device) is referred to as a control electrode, and other two terminals of the switch device are a first electrode and a second electrode respectively. Hereinafter, the present embodiment will be described in detail below by taking N-type transistors as an example.

As shown in FIG. 2, the input circuit 110 may comprise a first transistor M1. The first transistor M1 has a control electrode coupled to the signal input terminal IN, a first electrode coupled to the first voltage signal terminal VDD and a second electrode coupled to the first node PU.

The output circuit 120 may comprise a third transistor M3 and a first capacitor Cl. The third transistor M3 has a control electrode coupled to the first node PU, a first electrode coupled to the first clock signal terminal CLK and a second electrode coupled to the signal output terminal OUT. The first capacitor C1 has one terminal coupled to the first node PU and the other terminal coupled to the signal output terminal.

The first reset circuit 130 may comprise a second transistor M2. The second transistor M2 has a control electrode coupled to the reset signal terminal RST, a first electrode coupled to the second voltage signal terminal VSS and a second electrode coupled to the first node PU.

The second reset circuit 140 may comprise a fourth transistor M4 and a fifth transistor M5. The fourth transistor M4 has a control electrode coupled to the second clock signal terminal CLKB, a first electrode coupled to the third voltage signal terminal VGL and a second electrode coupled to the signal output terminal OUT. The fifth transistor M5 has a control electrode coupled to the second node PD, a first electrode coupled to the third voltage signal terminal VGL and a second electrode coupled to the signal output terminal OUT.

The pull-up control circuit 150 may comprise a seventh transistor M7. The seventh transistor M7 has a control electrode coupled to the second node PD, a first electrode coupled to the third voltage signal terminal VGL and a second electrode coupled to the first node PU.

The pull-down control circuit 160 may comprise a sixth transistor M6, an eighth transistor M8 and a second capacitor C2. The sixth transistor M6 has a control electrode coupled to the first node PU, a first electrode coupled to the third voltage signal terminal VGL and a second electrode coupled to the second node PD. The eighth transistor M8 has a control electrode and a first electrode coupled to the second clock signal terminal CLKB and a second electrode coupled to the second node PD. The second capacitor C2 has one terminal coupled to the second node PD and the other terminal coupled to the third voltage signal terminal VGL.

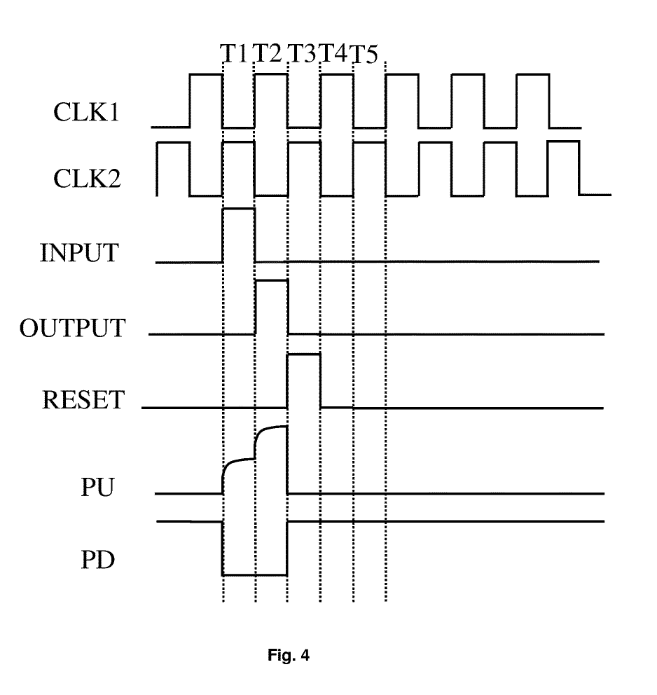

Next, an operation process of the shift register 100 shown in FIG. 2 during a forward scan will be described in detail with reference to a timing diagram shown in FIG. 4. In the following description, the first voltage signal Vdd is a high level signal acting as an operating voltage, the second voltage signal VSS is a low level signal, and the third voltage signal VGL is also a low level signal.

During a first period of time (T1), the first clock signal CLK1 is at a low level, the second clock signal CLK2 is at a high level, the input signal INPUT is at a high level, and the reset signal RESET is at a low level. During T1, the first transistor M1 is turned on, the input signal INPUT charges the first capacitor C1, and the voltage of the first node PU increases to a high level. In addition, the third transistor is turned on, so that the signal output terminal OUT outputs the first clock signal CLK1 at a low level as the output signal OUTPUT. The sixth transistor M6 is turned on to discharge the second capacitor C2, so that the voltage of the second node PD decreases to a low level. The fifth transistor M5 and the seventh transistor M7 are turned off to ensure stable signal output.

During a second period of time (T2), the first clock signal CLK1 is at a high level, the second clock signal CLK2 is at a low level, the input signal INPUT is at a low level, and the reset signal RESET is at a low level. During T2, the first transistor M1 is turned off, the first capacitor C1 is discharged, the voltage of the first node PU is further pulled up due to bootstrapping, and the voltage of the second node PD is maintained at a low level. As the voltage of the first node PU further increases relative to its voltage during the first period of time, the third transistor M3 is maintained in a turn-on state. Therefore, the signal output terminal OUT outputs the first clock signal CLK1 at a high level, that is, the signal output terminal outputs the output signal OUTPUT for driving a gate line. On the other hand, the sixth transistor M6 is maintained in a turn-on state, so that the fifth transistor M5 and the seventh transistor M7 are maintained to be turned off. At the same time, the fourth transistor M4 is turned off, which avoids that a high level signal output by the signal output terminal is pulled down to a low level VGL, thereby ensuring stable output of the signal of the signal output terminal.

During a third period of time (T3), the first clock signal CLK1 is at a low level, the second clock signal CLK2 is at a high level, the input signal INPUT is at a low level, and the reset signal RESET is at a high level. During T3, the second transistor M2 is turned on, so that the voltage of the first node PU is reset to a low level, and thereby the third transistor M3 is turned off. At the same time, the fourth transistor M4 is turned on and the output signal terminal OUT outputs the output signal OUTPUT at a low level. In addition, the eighth transistor M8 is turned on, so that the voltage of the second node PD increases to a high level and charges the second transistor C2. Therefore, the fifth transistor M5 and the seventh transistor M7 are turned on, so that the voltage of the first node PU and the signal output terminal OUT are maintained at a low level.

During a fourth period of time (T4), the first clock signal CLK1 is at a high level, the second clock signal CLK2 is at a low level, the input signal INPUT is at a low level, and the reset signal RESET is at a low level. During T4, the second transistor C2 is discharged to maintain the voltage of the second node PD at a high level. Therefore, it is ensured that the fifth transistor M5 and the seventh transistor M7 are turned on, so that the voltage of the first node PU and the signal output terminal OUT are maintained at a low level and the sixth transistor M6 is turned off. Therefore, a coupling noise voltage caused by the first clock signal CLK1 is eliminated to ensure stability of signal output.

During a fifth period of time (T5), the first clock signal CLK1 is at a low level, the second clock signal CLK2 is at a high level, the input signal INPUT is at a low level, and the reset signal RESET is at a low level. During T5, the eighth transistor M8 is turned on, so that the voltage of the second node PD is maintained at a high level while charging the second transistor C2. The fifth transistor M5 and the seventh transistor M7 are turned on, so that the voltage of the first node PU and the output signal OUTPUT are maintained at a low level, so as to ensure stability of signal output.

In subsequent periods of time, the shift register repeats the above operations during the fourth period of time (T4) and the fifth period of time (T5) in turn, so that the voltage of the first node PU and the output signal of the signal output terminal are maintained at a low level until the shift register receives the input signal INPUT at a high level at the signal input terminal IN.

As can be seen from the above description, the shift register according to the embodiment of the present disclosure maintain the signal output terminal OUT and the first node PU at a low level in a non-output state (i.e., when the output signal terminal OUT does not output a driving signal at a high level), to perform cyclic noise cancellation for the signal output terminal OUT and the first node, thereby eliminating an output noise, improving operation stability and extending the service life. At the same time, a few transistors are used in the shift register according to the embodiment of the present disclosure, and thus a narrow frame design of a display can be achieved.

The shift register according to the embodiments of the present disclosure can reduce the noise at the signal output terminal by only using a few elements, so as to maintain long-term and stable operations of the gate driving circuit.

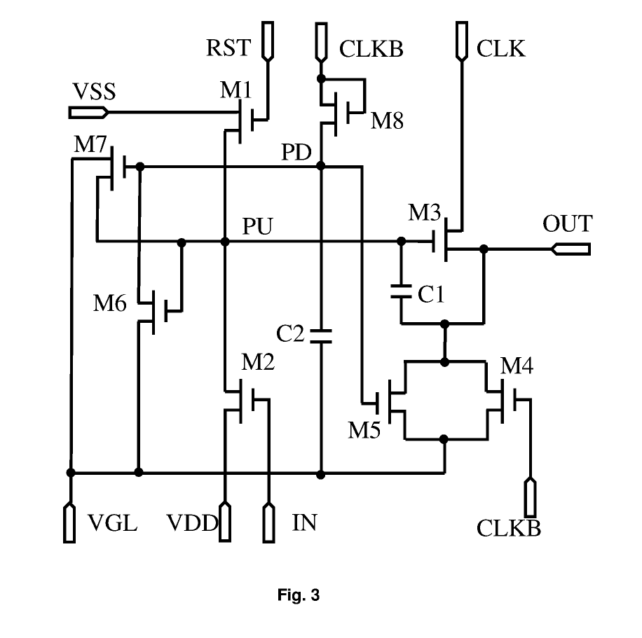

FIG. 3 illustrates a schematic circuit diagram of the shift register 100 shown in FIG. 1 during a reverse scan. The schematic circuit diagram is similar to the schematic circuit diagram of the shift register shown in FIG. 2 during a forward scan, except that the signal input terminal IN of the shift register in FIG. 3 corresponds to the reset signal terminal RST of the shift register in FIG. 2, the reset signal terminal RST of the shift register in FIG. 3 corresponds to the signal input terminal IN of the shift register in FIG. 2, the first voltage signal terminal VDD of the shift register in FIG. 3 corresponds to the second voltage signal terminal VSS of the shift register in FIG. 2, and the second voltage signal terminal VSS of the shift register in FIG. 3 corresponds to the first voltage signal terminal VDD of the shift register in FIG. 2.

Specifically, during the reverse scan, the second transistor M2 constitutes the input circuit 110. The second transistor M2 has a control electrode coupled to the signal input terminal IN, a first electrode coupled to the first voltage signal terminal VDD and a second electrode coupled to the first node PU.

The first transistor M1 constitutes the first reset circuit 130. The first transistor M1 has a control electrode coupled to the reset signal terminal RST, a first electrode coupled to the second voltage signal terminal VSS and a second electrode coupled to the first node PU.

In addition, configurations of the output circuit 120, the second reset circuit 140, the pull-up control circuit 150, and the pull-down control circuit 160 during the reverse scan are the same as those during the forward scan, and the description thereof will be omitted here.

It will be appreciated by those skilled in the art that the operation process of the disclosed shift register during the reverse scan is similar to that during the forward scan.

Specifically, during a first period of time (T1), the first clock signal CLK1 is at a low level, the second clock signal CLK2 is at a high level, the input signal INPUT is at a high level, and the reset signal RESET is at a low level. During T1, the second transistor M2 is turned on, the input signal INPUT charges the first capacitor C1, and the voltage of the first node PU increases to a high level. In addition, the third transistor is turned on, so that the signal output terminal OUT outputs the first clock signal CLK1 at a low level as the output signal OUTPUT. The sixth transistor M6 is turned on to discharge the second capacitor C2, so that the voltage of the second node PD decreases to a low level. The fifth transistor M5 and the seventh transistor M7 are turned off to ensure stable signal output.

During a second period of time (T2), the first clock signal CLK1 is at a high level, the second clock signal CLK2 is at a low level, the input signal INPUT is at a low level, and the reset signal RESET is at a low level. During T2, the second transistor M2 is turned off, the first capacitor C1 is discharged, the voltage of the first node PU is further pulled up due to bootstrapping, and the voltage of the second node PD is maintained at a low level. As the voltage of the first node PU further increases relative to its voltage during the first period of time, the third transistor M3 is maintained in a turn-on state. Therefore, the signal output terminal OUT outputs the first clock signal CLK1 at a high level, that is, the signal output terminal outputs the output signal OUTPUT for driving a gate line. On the other hand, the sixth transistor M6 is maintained in a turn-on state, so that the fifth transistor M5 and the seventh transistor M7 are maintained to be turned off. At the same time, the fourth transistor M4 is turned off, which avoids that a high level signal output by the signal output terminal is pulled down to a low level VGL, thereby ensuring stable output of the signal of the signal output terminal.

During a third period of time (T3), the first clock signal CLK1 is at a low level, the second clock signal CLK2 is at a high level, the input signal INPUT is at a low level, and the reset signal RESET is at a high level. During T3, the first transistor M1 is turned on, so that the voltage of the first node PU is reset to a low level, and thereby the third transistor M3 is turned off. At the same time, the fourth transistor M4 is turned on and the output signal terminal OUT outputs the output signal OUTPUT at a low level. In addition, the eighth transistor M8 is turned on, so that the voltage of the second node PD increases to a high level and charges the second transistor C2. Therefore, the fifth transistor M5 and the seventh transistor M7 are turned on, so that the voltage of the first node PU and the signal output terminal OUT are maintained at a low level.

In addition, operations during the fourth period of time (T4) and the fifth period of time (T5) at the time of the reverse scan are similar to those at the time of the forward scan in FIG. 3, and the description thereof will be omitted here.

In the embodiment of the present disclosure, the disclosed shift register can also maintain the voltage of the first node PU and the voltage of the signal output terminal OUT at a low level in a non-output state during the reverse scan, thereby eliminating the noise.

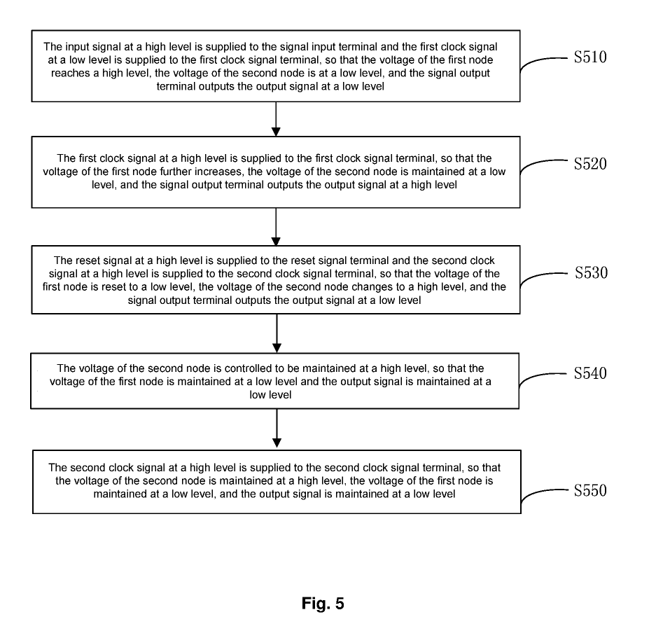

FIG. 5 is a schematic flowchart of a method for driving the shift register 100 shown in FIG. 1 according to an embodiment of the present disclosure. In the embodiment of the present disclosure, the first voltage signal Vdd is a high level signal, the second voltage signal Vss is a low level signal, and the third voltage signal Vgl is also a low level signal.

In step S510, the input signal at a high level is supplied to the signal input terminal and the first clock signal at a low level is supplied to the first clock signal terminal, so that the voltage of the first node reaches a high level, the voltage of the second node is at a low level, and the signal output terminal outputs the output signal at a low level.

In step S520, the first clock signal at a high level is supplied to the first clock signal terminal, so that the voltage of the first node further increases, the voltage of the second node is maintained at a low level, and the signal output terminal outputs the output signal at a high level.

In step S530, the reset signal at a high level is supplied to the reset signal terminal and the second clock signal at a high level is supplied to the second clock signal terminal, so that the voltage of the first node is reset to a low level, the voltage of the second node changes to a high level, and the signal output terminal outputs the output signal at a low level.

In step S540, the voltage of the second node is controlled to maintain at a high level, so that the voltage of the first node is maintained at a low level and the output signal is maintained at a low level.

In step S550, the second clock signal at a high level is supplied to the second clock signal terminal, so that the voltage of the second node is maintained at a high level, the voltage of the first node is maintained at a low level, and the output signal is maintained at a low level.

The schematic flowchart of the method for driving the shift register 100 during a forward scan is described above. It is to be understood by those skilled in the art that a flow of a method for driving the shift register 100 during a reverse scan is similar to the flow described above, except that a signal which is equivalent to the second voltage signal Vss at a low level during the forward scan is supplied to the first voltage signal terminal VDD, a signal which is equivalent to the first voltage signal Vdd at a high level during the forward scan is supplied to the second voltage signal terminal VSS, a signal which is equivalent to the reset signal during the forward scan is supplied to the signal input terminal IN, and a signal which is equivalent to the input signal during the forward scan is supplied to the reset signal terminal RST. The detailed description thereof will be omitted here.

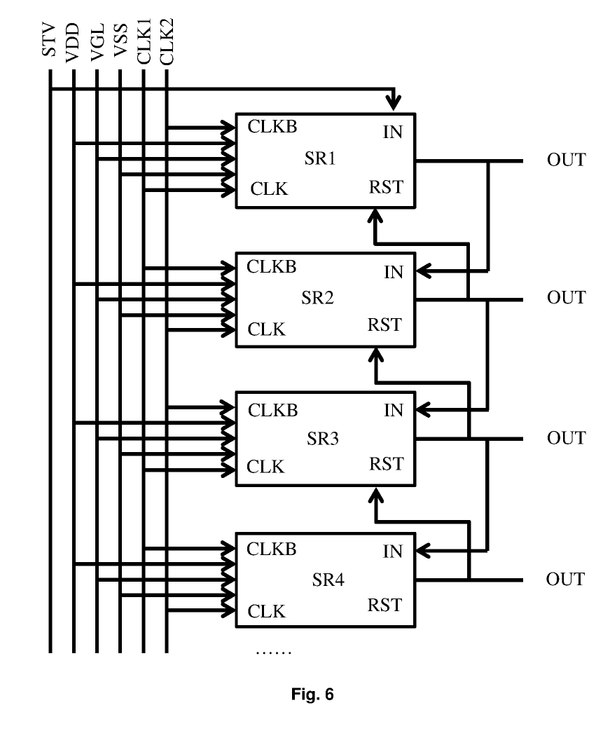

FIG. 6 illustrates a schematic structure diagram of a gate driving apparatus 600 according to an embodiment of the present disclosure. As shown in FIG. 6, the gate driving apparatus 600 may comprise N+1 stages of shift registers SR1, SR2, . . . , SRN, SR(N+1) which are connected in cascade, wherein each stage of shift registers may be implemented using the shift register structure described above.

In the gate driving apparatus 600, ports of each stage of shift registers may comprise a first voltage signal terminal VDD, a second voltage signal terminal VSS, a third voltage signal terminal VGL, a first clock signal input terminal CLK, a second clock signal terminal CLKB, a signal input terminal IN, a reset signal terminal RST and a signal output terminal OUT.

A signal output terminal OUT of each stage of shift registers SRn (where n=1 . . . N) is coupled to a signal input terminal IN of a next stage of shift registers SR(n+1), a reset signal terminal RST of each stage of shift registers SRn is coupled to a signal output terminal OUT of the next stage of shift registers SR(n+1), and a signal input terminal INPUT of a first stage of shift registers SR1 inputs a frame start signal STV. For example, a reset signal terminal RST of the first stage of shift registers SR1 receives an output signal OUTPUT from a signal output terminal OUT of a second stage of shift registers SR2 as a reset signal RESET of the first stage of shift registers SR1. A signal input terminal IN of the second stage of shift registers SR2 receives an output signal OUTPUT from a signal output terminal OUT of the first stage of shift registers SR1 as an input signal INPUT of the second stage of shift registers SR2.

In addition, clock signals input to first clock signal input terminals CLK of two adjacent stages of shift registers have opposite phases to each other, and clock signals input to second clock signal terminals of the two adjacent stages of shift registers have opposite phases to those of corresponding first clock signal terminals, respectively. For example, a first clock signal terminal CLK of an odd row of shift registers inputs a first clock signal CLK1, and a second clock signal terminal CLKB of the odd row of shift registers inputs a second clock signal CLK2, while a first clock signal terminal CLK of an even row of shift registers inputs the second clock signal CLK2, and a second clock signal terminal CLKB of the even row of shift registers inputs the first clock signal CLK1, wherein the first clock signal CLK1 and the second clock signal CLK2 have opposite phases.

While several embodiments of the present disclosure have been described in detail above, the protection scope of the present disclosure is not limited thereto. It will be apparent to those skilled in the art that various modifications, substitutions, or alterations can be made in the embodiments of the present disclosure without departing from the spirit and scope of the present disclosure. The protection scope of the present disclosure is defined by the appended claims.

I/we claim:

1. A shift register, comprising:
an input circuit coupled to a signal input terminal, a first voltage signal terminal, and a first node and configured to supply a first voltage signal from the first voltage signal terminal to the first node according to an input signal from the signal input terminal;
an output circuit coupled to a first clock signal terminal, a signal output terminal, and the first node and configured to supply a first clock signal from the first clock signal terminal to the signal output terminal, as an output signal, according to the voltage of the first node;
a first reset circuit coupled to a reset signal terminal, a second voltage signal terminal, and the first node and configured to supply a second voltage signal from the second voltage signal terminal to the first node according to a reset signal from the reset signal terminal, to reset the voltage of the first node;
a second reset circuit coupled to a second clock signal terminal, a third voltage signal terminal, a second node, and the signal output terminal and configured to supply a third voltage signal from the third voltage signal terminal to the signal output terminal according to a second clock signal from the second clock signal terminal or a voltage of the second node, to reset the output signal;
a pull-up control circuit coupled to the third voltage signal terminal, the first node, and the second node and configured to control the voltage of the first node according to the voltage of the second node; and
a pull-down control circuit coupled to the second clock signal terminal, the first node, the second node, and the third voltage signal terminal and configured to control the voltage of the second node according to the voltage of the first node and configured to control the voltage of the second node to be an effective voltage in response to the voltage of the first node being a non-effective voltage.

2. The shift register according to claim 1, wherein the input circuit comprises:
a first transistor having a control electrode coupled to the signal input terminal, a first electrode coupled to the first voltage signal terminal, and a second electrode coupled to the first node.

3. The shift register according to claim 1, wherein the first reset circuit comprises:
a second transistor having a control electrode coupled to the reset signal terminal, a first electrode coupled to the second voltage signal terminal, and a second electrode coupled to the first node.

4. The shift register according to claim 1, wherein the output circuit comprises:
a third transistor having a control electrode coupled to the first node, a first electrode coupled to the first clock signal terminal, and a second electrode coupled to the signal output terminal; and
a first capacitor coupled between the first node and the signal output terminal.

5. The shift register according to claim 1, wherein the second reset circuit comprises:
a fourth transistor having a control electrode coupled to the second clock signal terminal, a first electrode coupled to the third voltage signal terminal, and a second electrode coupled to the signal output terminal; and
a fifth transistor having a control electrode coupled to the second node, a first electrode coupled to the third voltage signal terminal and a second electrode coupled to the signal output terminal.

6. The shift register according to claim 1, wherein the pull-down control circuit comprises:
a sixth transistor having a control electrode coupled to the first node, a first electrode coupled to the third voltage signal terminal, and a second electrode coupled to the second node;
a seventh transistor having a control electrode and a first electrode both coupled to the second clock signal terminal and a second electrode coupled to the second node; and
a second capacitor coupled between the second node and the third voltage signal terminal.

7. The shift register according to claim 1, wherein the pull-up control circuit comprises:
an eighth transistor having a control electrode coupled to the second node, a first electrode coupled to the third voltage signal terminal, and a second electrode coupled to the first node.

8. The shift register according to claim 1, wherein transistors used in various circuits are N-type transistors or P-type transistors.

9. The shift register according to claim 1, wherein the first clock signal has an opposite phase to that of the second clock signal.

10. A method for driving the shift register according to claim 1, wherein the first voltage signal terminal outputs the first voltage signal at a high level, the second voltage signal terminal outputs the second voltage signal at a low level, and the third voltage signal terminal outputs the third voltage signal at a low level, the method comprising:
supplying the input signal at a high level to the signal input terminal and supplying the first clock signal at a low level to the first clock signal terminal during a first period of time, so that the voltage of the first node reaches a high level, the voltage of the second node is at a low level, and the signal output terminal outputs the output signal at a low level;
supplying the first clock signal at a high level to the first clock signal terminal during a second period of time, so that the voltage of the first node further increases, the voltage of the second node is maintained at a low level, and the signal output terminal outputs the output signal at a high level;
supplying the reset signal at a high level to the reset signal terminal and supplying the second clock signal at a high level to the second clock signal terminal during a third period of time, so that the voltage of the first node is reset to a low level, the voltage of the second node changes to a high level, and the signal output terminal outputs the output signal at a low level;
controlling the voltage of the second node to be maintained at a high level during a fourth period of time, so that the voltage of the first node is maintained at a low level and the output signal is maintained at a low level; and
supplying the second clock signal at a high level to the second clock signal terminal during a fifth period of time, so that the voltage of the second node is maintained at a high level, the voltage of the first node is maintained at a low level, and the output signal is maintained at a low level.

11. The method according to claim 10, wherein the first voltage signal terminal outputs the second voltage signal at a low level, and the second voltage signal terminal outputs the first voltage signal at a high level, and wherein the reset signal is supplied to the signal input terminal, and the input signal is supplied to the reset signal terminal.

12. A gate driving apparatus, comprising multiple cascaded stages of shift registers,
wherein each stage of shift registers is the shift register according to claim 1, wherein the signal output terminal of each stage of shift registers is coupled to the signal input terminal of the next stage of shift registers, and the rest signal terminal of each stage of shift registers is coupled to the signal output terminal of the next stage of shift registers.

13. The gate driving apparatus according to claim 12, wherein clock signals for the first clock signal terminals of two adjacent stages of shift registers have opposite phases to each other, and clock signals for the second clock signal terminals of the two adjacent stages of shift registers have opposite phases to those of corresponding first clock signal terminals, respectively.

14. An array substrate comprising the gate driving apparatus according to claim 12.

15. A display apparatus comprising the array substrate according to claim 14.
